(19) United States
(12) Patent Application Publication
(10) Pub. No.: US 2007/0040269 A1
(43) Pub. Date: Feb. 22, 2007

(54) Thermally enhanced cavity down ball grid array package

(75) Inventors: Pei-Haw Tsao, Tai-chung (TW); Frank Wu, Kaohsiung (TW); Chung-Yi Lin, Tainan (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD., Hsin-Chu (TW)

(21) Appl. No.: 11/207,886

(22) Filed: Aug. 22, 2005

(51) Int. Cl. H01L 23/34

(52) U.S. Cl. 257/718

(57) ABSTRACT

A thermally-enhanced cavity down ball grid array (CDBGA) package is provided. In one embodiment, the CDBGA package comprises a heat dissipating substrate having a heat spreader and a chip carrier, the chip carrier having a cavity therethrough to allow a chip to be attached to the heat spreader. A chip having an active surface and a corresponding back surface, has the back surface of the chip mounted on the heat spreader. A dummy chip is attached to the active surface of the chip. The dummy chip has a coefficient of thermal expansion approximately equal to the coefficient of thermal expansion of the chip. An encapsulant encapsulates the chip and portions of the dummy chip.

Dummy chip 90 has a coefficient of thermal expansion (CTE) approximately equal to the coefficient of thermal expansion of the chip 40. Because the CTE of the dummy chip 90 is approximately equal to the CTE of the chip 40 and the amount of the encapsulant 60 used will be substantially reduced due to present of the dummy chip, this minimizes the thermal stresses and warpage induced on the chip 40, thereby reducing the occurrence of delamination in chip 40.

### BACKGROUND

The present invention relates generally to a cavity down ball grid array (CDBGA) package and a fabrication method thereof. More particularly, the present invention relates to an improved CDBGA package with high reliability With the increasing need for high-density devices for use in lightweight, portable electronics, there has been a gradual shift in the sizes of integrated circuits and their package configurations. This gradual shift has resulted in developing various techniques for different package types.

A ball grid array (BGA) package is a common packaging method in the field of electronic-packages. The BGA package utilizes adhesive or tape materials to adhere a back surface of a chip onto a substrate. A molding compound encapsulates the chip and bond wires. A plurality of solder balls are formed on the substrate. The above-mentioned structure of a BGA package can utilize solder balls to electrically connect to external circuits. The layout of the solder balls of the BGA package is in a matrix form and it is suitable for a high-density circuit IC because it can contain a large quantity of external connections for IV circuits.

However, although the packaging size is reduced, the integration of the device is increased. Thus, the heat produced per unit of area of the device increases. Therefore a heat dissipation problem occurs. To improve the cooling of the chip, a cavity down ball grid array (CDBGA) package is often utilized. In fact for devices that have high power dissipation, cavity down BGA packages are frequently used. A cavity in the CDBGA package allows the chip to be mounted in a “chip down” orientation. The CDBGA package has better heat dissipation because the back surface of the chip is in contact with a heat spreader, and heat is transferred through the heat spreader to the external environment. A heat sink may be attached to the heat spreader for enhanced performance.

FIG. 1 shows a cross-sectional view of a conventional semi-finished CDBGA package 10. CDBGA package 10 includes a heat spreader 20, a chip carrier 30, and a chip 40. Chip carrier 30 is attached to the heat spreader 20 by an adhesive and chip carrier 30 has a cavity therethrough to allow chip 40 to be attached to the heat spreader 20. The back side (non active side) of chip 40 is attached onto a surface of the heat spreader by an adhesive material. Chip 40 is then wired to chip carrier 30 by bond wires 50 so as to make electrical connection with a printed circuit board (not shown). Chip 40 and bond wires 50 are then encapsulated in an encapsulant 60. A plurality of solder balls 70 are formed on chip carrier 30 for electrical attachment to a printed circuit board.

Due to the inherent coefficient of thermal expansion (CTE) mismatches between at least the chip 40 and encapsulant 60 during testing or operation, thermal stresses and high package warpage are frequently induced in the CDBGA package 10. These high thermal stresses and warpage may cause delamination in the chip 40, and at least between the chip 40 and encapsulant 60, thereby degrading the long-term operating reliability of the CDBGA package 10.

For these reasons and other reasons that will become apparent upon reading the following detailed description, there is a need for an improved CDBGA package that reduces and/or eliminates the thermal stress induced reliability problems associated with conventional CDBGA packages.

### SUMMARY

The present invention is directed to a thermally-enhanced cavity down ball grid array (CDBGA) package. In one embodiment, the CDBGA package comprises a heat dissipating substrate having a heat spreader and a chip carrier, the chip carrier having a cavity therethrough to allow a chip to be attached to the heat spreader. A chip having an active surface and a corresponding back surface, has the back surface of the chip mounted on the heat spreader. A dummy chip is attached to the active surface of the chip. An encapsulant thereafter encapsulates the chip and portions of the dummy chip. The dummy chip has a coefficient of thermal expansion approximately equal to the coefficient of thermal expansion of the chip. Because the CTE of the dummy chip is approximately equal to the CTE of the chip, the amount of the encapsulant used will be substantially reduced. This minimizes the thermal stresses and warpage induced on the chip, thereby reducing the occurrence of delamination in the chip.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a conventional semi-finished cavity down ball grid array package.

FIG. 2 is a cross-sectional view of a semi-finished cavity down ball grid array package according to an aspect of the present invention.

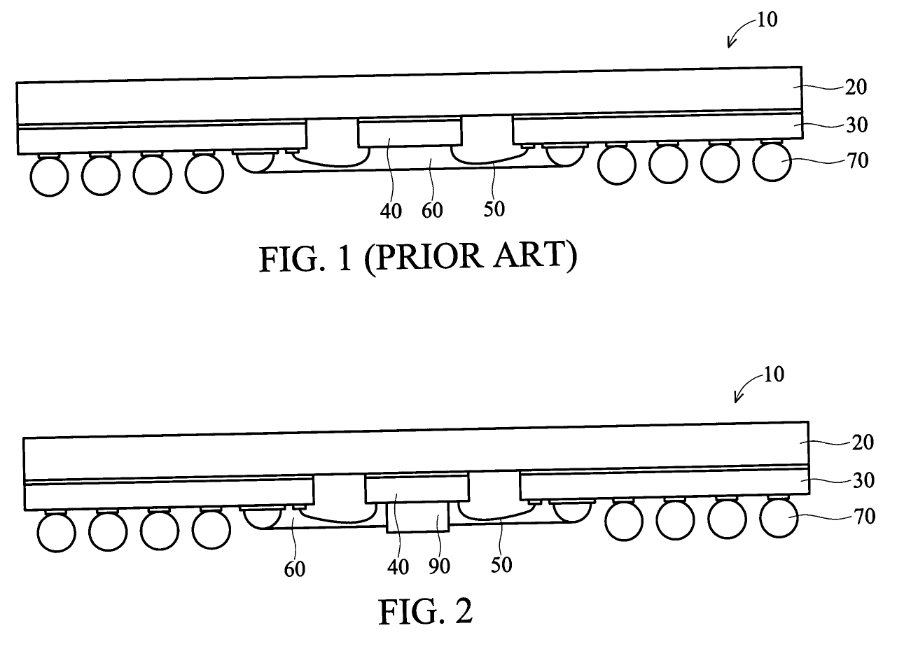

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present preferred embodiments of the present invention, examples of which are illustrated in the accompanying drawings.

Referring to FIG. 2, illustrated is a cross-sectional view of a semi-finished cavity down ball grid array package 10 according to an aspect of the present invention. CDBGA package 10 includes a heat spreader 20, a chip carrier 30, and a chip 40. The heat spreader 20 is provided to dissipate heat produced during operation of the chip. Heat spreader 20 is formed of a highly conductive metal such as copper but it is contemplated that other materials, known for high conductivity, could also be used. For instance, nickel or aluminum can also be used with the aluminum typically provided with a surface treatment such as an anodized or chromate-conversion later.

During operation of chip 40, heat is generated. This heat must be dissipated from the chip 40 in order for it to continue to function properly. While dissipating heat, chip 40 must still be securely bonded to heat spreader 20 by means of an adhesive; otherwise the bond formed between the chip 40 and the heat spreader 20 will fatigue, delaminate and ultimately fail. For these reasons, the adhesive must possess a high thermal conductivity and must also must exhibit a high bond strength to the metal of the heat spreader 20. The backside (non active side) of chip 40 is attached onto a surface of the heat spreader 20 by the adhesive material. Thermal adhesives useful for adhering semiconductor chips to heat sinks are well-known in the art and any such thermal adhesive can be used in accordance with the present invention. Examples of well-known thermal adhesives are the epoxy resins, acrylic resins and silicone resins. Typically, these resins are filled to a greater or lesser degree with heat conducting fillers such as silver, alumina, aluminum nitrate or other particles, fibers or composites for improving thermal conductivity.

Also shown in FIG. 2 is chip carrier 30. Chip carrier 30 can be comprised of a copper material, a glass-epoxy such as FR4 or any other well-known carrier material. Chip carrier 30 has a cavity therethrough to allow chip 40 to be attached to the heat spreader 20. Chip carrier 30 may contain routing traces, surface pads, power/ground planes and vias, etc. which electrically connect later to be formed bond wires and solder balls together.

Chip 40 is then wired to chip carrier 30 by bond wires 50 so as to make electrical connection with a printed circuit board (not shown). Although bond wires 50 are employed to electrically couple chip 40 to chip carrier 30, any means for coupling the chip 40 to the chip carrier 30 such as by way of solder bumps as known to those skilled in the art are within the scope of the present disclosure.

Further shown in FIG. 2, CDBGA package 10 also includes a thermally enhanced dummy chip 90 attached to the active surface of the chip 40. Dummy chip 90 may be attached to chip 40 by a tape or an adhesive, such as epoxy resins, acrylic resins and silicone resins. Thermal adhesives are well-known in the art and any such adhesives may be used in accordance with the present invention so long as the adhesive possesses high thermal conductivity and exhibit high bond strength. Preferably, the adhesive is chosen to match or accommodate the coefficients of thermal expansion of the dummy chip 90 and the chip 40. An encapsulant process is then performed to encapsulate at least chip 40, bond wires 50 and portion of the dummy chip 90 in an encapsulant 60. A ball placing process is performed and through a reflow process a plurality of solder balls 70 are formed on chip carrier 30 for electrical attachment to an external substrate, such as a printed circuit board. Although solder balls 70 are shown and described, it is to be understood that the CDBGA package 10 may have other contacts such as pins.

Dummy chip 90 has a coefficient of thermal expansion (CTE) approximately equal to the coefficient of thermal expansion of the chip 40. Because the CTE of the dummy chip 90 is approximately equal to the CTE of the chip 40 and the amount of the encapsulant 60 used will be substantially reduced due to present of the dummy chip, this minimizes the thermal stresses and warpage induced on the chip 40, thereby reducing the occurrence of delamination in chip 40. Dummy chip 90 may be comprised of silicon, silicon dioxide, or glass. In another embodiment, dummy chip 90 comprises a metal such as, for example copper. In yet another embodiment, dummy chip 90 comprises a material having a CTE approximately equal to the CTE of a chip. It is understood that the material, shape, and thickness of dummy chip 90 may be adjusted to match either the CTE of the chip 40, heat spreader 20, or encapsulant 60 to meet the design criteria for a particular application.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A cavity down ball grid array (CDBGA) package comprising:
a heat dissipating substrate comprising a heat spreader and a chip carrier, the chip carrier having a cavity therethrough to allow a chip to be attached to the heat spreader;
at least one chip having an active surface and a corresponding back surface, wherein the back surface of the chip is mounted on the heat spreader;
a dummy chip attached to the active surface of the chip; and
an encapsulant encapsulating the chip and portions of the dummy chip.

2. The CDBGA package of claim 1, wherein the dummy chip is attached to the chip by an adhesive.

3. The CDBGA package of claim 1, wherein the coefficient of thermal expansion (CTE) of the dummy chip is approximately equal to the coefficient of thermal expansion of the chip.

4. The CDBGA package of claim 1, wherein the dummy chip comprises silicon.

5. The CDBGA package of claim 1, wherein the dummy chip comprises silicon dioxide.

6. The CDBGA package of claim 1, wherein the dummy chip comprises metal.

7. The CDBGA package of claim 1, wherein the dummy chip comprises a material being thermally conductive.

8. The CDBGA package of claim 1, wherein a material, shape, and thickness of the dummy chip may be adjusted to match the coefficient of thermal expansion of the chip.

9. The CDBGA package of claim 1, wherein a material, shape, and thickness of the dummy chip may be adjusted to match the coefficient of thermal expansion of the encapsulant.

10. A method of making a CDBGA package, comprising:
providing a heat dissipating substrate comprising a heat spreader and a chip carrier, the chip carrier having a cavity therethrough to allow a chip to be attached to the heat spreader;
providing at least one chip having an active surface and a corresponding back surface, wherein the back surface of the chip is mounted on the heat spreader;
providing a dummy chip attached to the active surface of the chip; and
encapsulating the chip and portions of the dummy chip in an encapsulant.

11. The method of claim 10, wherein the dummy chip is attached to the chip by an adhesive.

12. The method of claim 10, wherein the coefficient of thermal expansion (CTE) of the dummy chip is approximately equal to the coefficient of thermal expansion of the chip.

13. The method of claim 10, wherein the dummy chip comprises silicon.

14. The method of claim 10, wherein the dummy chip comprises silicon dioxide.

15. The method of claim 10, wherein the dummy chip comprises metal.

16. The method of claim 10, wherein the dummy chip comprises a material being thermally conductive.

17. The method of claim 10, wherein a material, shape, and thickness of the dummy chip may be adjusted to match the coefficient of thermal expansion of the chip.

18. The method of claim 10, wherein a material, shape, and thickness of the dummy chip may be adjusted to match the coefficient of thermal expansion of the encapsulant.
